(19) United States
(12) Patent Application Publication
(10) Pub. No.: US 2013/0087881 A1
(43) Pub. Date: Apr. 11, 2013

(54) SEMICONDUCTOR INTEGRATED CIRCUIT DEVICE

(71) Applicant: PANASONIC CORPORATION, Osaka (JP)

(72) Inventors: Tomoaki IKEGAMI, Kanagawa (JP); Hidetoshi NISHIMURA, Osaka (JP)

(73) Assignee: PANASONIC CORPORATION, Osaka (JP)

(21) Appl. No.: 13/691,071

(22) Filed: Nov. 30, 2012

Related U.S. Application Data
(63) Continuation of application No. PCT/JP2012/000133, filed on Jan. 11, 2012.

(30) Foreign Application Priority Data
Apr. 6, 2011 (JP) 2011-084299

(51) Int. Cl. H01L 27/04

(52) U.S. Cl. CPC H01L 27/04
USPC 257/499

(57) ABSTRACT

An interconnect plug which connects a first circuit metal interconnect to a second circuit metal interconnect provided above the first circuit metal interconnect is disposed near a feeding plug which connects a first feeding metal interconnect to a second feeding metal interconnect provided above the first feeding metal interconnect. The feeding plug and the interconnect plug are displaced relative to each other in a direction in which the first feeding metal interconnect extends.

### CROSS-REFERENCE TO RELATED APPLICATION

This is a continuation of PCT International Application PCT/JP2012/000133 filed on Jan. 11, 2012, which claims priority to Japanese Patent Application No. 2011-084299 filed on Apr. 6, 2011. The disclosures of these applications including the specifications, the drawings, and the claims are hereby incorporated by reference in their entirety.

### BACKGROUND

The present disclosure relates to layouts of semiconductor integrated circuit devices, and specifically to a technique which is effective in reducing both the size and the area of a semiconductor integrated circuit device.

Conventionally, in semiconductor integrated circuit devices, transistors having various widths and lengths are freely arranged and interconnected to obtain various circuit units having desired functions. The circuit units are referred to as cells. The cells are arranged and interconnected in combination with each other to obtain large scale integration (LSI) circuit devices.

In recent years, as the areas of cells are reduced to lower the cost of chips, not only reducing dimensions of transistors and interconnects disposed in the cells, but also arranging the transistors and the interconnects without wasting the areas of the cells has been required. Thus, the following layout problems arise, in particular, in complicated cells such as flip-flop circuits and latch circuits.

FIG. 10 is a layout plan view illustrating a latch circuit cell having a reduced area. In FIG. 10, gate interconnects Gn (n is an integer, the same hereinafter) and active regions Dn in which the sources and the drains will be formed form transistors Tn, and above the gate interconnects Gn and the active regions Dn, first-layer metal interconnects Mn are formed to connect the transistors Tn to each other. Feeding active regions DV0-DV1 and feeding first-layer metal interconnects MV0-MV1 for feeding source potentials to the transistors Tn extend in the transverse direction in the figure at upper and lower ends of the cell. Moreover, interconnect plugs Pn configured to connect the gate interconnects Gn or the active regions Dn to the metal interconnects Mn, and feeding plugs PVn configured to connect the active regions DV0-DV1 to the metal interconnects MV0-MV1 are formed. In order to render the transistors Tn less susceptible to a source potential reduction, generally, the plurality of feeding plugs PVn are arranged at equal intervals. That is, the centers of the feeding plugs PVn are located on grid lines Ln, where the pitch S0 between the grid lines Ln has a predetermined length. With this configuration, when a plurality of cells each of which has a width defined as the integral multiple of the grid are arranged to be adjacent to each other in the vertical and horizontal directions thereof, the feeding plugs of the cells can be arranged to overlap each other, so that the feeding plugs can be densely arranged without being inhibited by each other.

Here, from the point of view of manufacturing process, when the interval between plugs arranged closely to each other is small, a short circuit is formed between the plugs, and desired circuit operation may not be obtained. To avoid the problem, the interval between the interconnect plug Pn and the feeding plug PVn has to be larger than the interval between the feeding plugs PVn. For example, in FIG. 10, the interval between the interconnect plug P14 and the feeding plugs PV6, PV7, the interval between the interconnect plug P24 and the feeding plugs PV10, PV11, the interval between the interconnect plug P15 and the feeding plugs PV21, PV22, and the interval between the interconnect plug P20 and the feeding plugs PV23, PV24 have to be increased. Moreover, even when the potential of the gate interconnect Gn is not significantly different from the source potential of the transistor Tn, from the point of view of design rule and manufacturing process, the interval between the interconnect plug Pn and the feeding plug PVn has to be increased at a certain extent. However, in order to do so, the cell has to be extended in the vertical direction, which increases the cell area. This tendency is significant in a cell whose height is reduced.

As a measure to solve the problem, Japanese Patent Publication No. 2010-067799 has proposed to omit some of the feeding plugs PVn. For example, in an example illustrated in FIG. 11, the feeding plugs PV6, PV7, PV10, PV11, PV21-PV24 of FIG. 10 are omitted. With this configuration, the reduced-area layout of the cell can be maintained, while the interval between the interconnect plug Pn and the feeding plug PVn can be satisfactorily increased, thereby stabilizing the circuit operation.

### SUMMARY

In the example of Japanese Patent Publication No. 2010-067799, some of the feeding plugs PVn are omitted to maintain the reduced-area layout of the cell, while a satisfactory wide interval between the interconnect plug Pn and the feeding plug PVn are ensured.

However, it may be difficult to omit feeding plugs above the feeding metal interconnects, for example, feeding plugs included in a stacked via structure configured to connect the feeding metal interconnects to power supply strap interconnects above the feeding metal interconnects. For this reason, even when interconnect plugs receiving different potentials exist near an interconnect layer identical with a layer including feeding plugs, the feeding plugs cannot be omitted, and thus satisfactory wide intervals between the feeding plugs and the interconnect plugs may not be ensured. In order to avoid the problem, for example, a circuit metal interconnect provided with interconnect plugs may be disposed away from the feeding metal interconnects. However, in this case, the cell has to be extended in the vertical direction, which increases the cell area.

In one general aspect, the instant application describes a semiconductor integrated circuit device which has a layout structure capable of ensuring a satisfactory interval between an interconnect plug and a feeding plug to maintain stability of circuit operation without increasing the area.

In a first aspect of the present disclosure, a semiconductor integrated circuit device including a standard logic cell includes: a first feeding metal interconnect formed in a first interconnect layer and extending in a first direction; a second feeding metal interconnect formed in a second interconnect layer above the first interconnect layer and extending in the first direction to overlap the first feeding metal interconnect; a first circuit metal interconnect formed in the first interconnect layer in the standard logic cell; a second circuit metal interconnect formed in the second interconnect layer in the standard logic cell and extending in the first direction to overlap the first circuit metal interconnect; a feeding plug configured to connect the first feeding metal interconnect to the second feeding metal interconnect; and an interconnect plug configured to connect the first circuit metal interconnect to the second circuit metal interconnect, wherein the second circuit metal interconnect is disposed in the standard logic cell to be closer to the second feeding metal interconnect than any other circuit metal interconnects formed in the second interconnect layer are, and have a portion overlapping the second feeding metal interconnect when viewed in a second direction perpendicular to the first direction, and the feeding plug and the interconnect plug are arranged in different positions in the first direction.

With this configuration, the interconnect plug which connects the first circuit metal interconnect to the second circuit metal interconnect provided above the first circuit metal interconnect is disposed near the feeding plug which connects the first feeding metal interconnect to the second feeding metal interconnect provided above the first feeding metal interconnect. The feeding plug and the interconnect plug are disposed in different positions in the first direction. That is, the feeding plug and the interconnect plug are displaced relative to each other in the first direction. Thus, a satisfactory interval can be ensured between the feeding plug and the interconnect plug which are close to each other, so that a problem where the plugs are electrically short-circuited can be avoided without increasing the area.

In a second aspect of the present disclosure, a semiconductor integrated circuit device including a standard logic cell includes: a first feeding metal interconnect formed in a first interconnect layer and extending in a first direction; a second feeding metal interconnect formed in a second interconnect layer above the first interconnect layer and extending in the first direction to overlap the first feeding metal interconnect; a first circuit metal interconnect formed in the first interconnect layer in the standard logic cell; a second circuit metal interconnect formed in the second interconnect layer in the standard logic cell and extending in the first direction to overlap the first circuit metal interconnect; a feeding plug configured to connect the first feeding metal interconnect to the second feeding metal interconnect; and an interconnect plug configured to connect the first circuit metal interconnect to the second circuit metal interconnect, wherein the second circuit metal interconnect is disposed in the standard logic cell to be closer to the second feeding metal interconnect than any other circuit metal interconnects formed in the second interconnect layer are, and have a portion overlapping the second feeding metal interconnect when viewed in a second direction perpendicular to the first direction, and a center of the interconnect plug in the second direction is shifted from a center of the second circuit metal interconnect in the second direction at an arrangement position of the interconnect plug in a direction away from the feeding plug.

With this configuration, the interconnect plug which connects the first circuit metal interconnect to the second circuit metal interconnect provided above the first circuit metal interconnect is disposed near the feeding plug which connects the first feeding metal interconnect to the second feeding metal interconnect provided above the first feeding metal interconnect. The center of the interconnect plug in the second direction is shifted from the center of the second circuit metal interconnect in the second direction at the arrangement position of the interconnect plug in a direction away from the feeding plug. That is, the interconnect plug is displaced in a direction away from the feeding plug. Thus, a satisfactory interval can be ensured between the feeding plug and the interconnect plug which are close to each other, so that a problem where the plugs are electrically short-circuited can be avoided without increasing the area.

In a third aspect of the present disclosure, a semiconductor integrated circuit device including a standard logic cell includes: a first feeding metal interconnect formed in a first interconnect layer and extending in a first direction; a second feeding metal interconnect formed in a second interconnect layer above the first interconnect layer and extending in the first direction to overlap the first feeding metal interconnect; a first circuit metal interconnect formed in the first interconnect layer in the standard logic cell; a second circuit metal interconnect formed in the second interconnect layer in the standard logic cell and extending in the first direction to overlap the first circuit metal interconnect; a feeding plug configured to connect the first feeding metal interconnect to the second feeding metal interconnect; and an interconnect plug configured to connect the first circuit metal interconnect to the second circuit metal interconnect, wherein the second circuit metal interconnect is disposed in the standard logic cell to be closer to the second feeding metal interconnect than any other circuit metal interconnects formed in the second interconnect layer are, and have a portion overlapping the second feeding metal interconnect when viewed in a second direction perpendicular to the first direction, and a center of the feeding plug in the second direction is shifted from a center of the first feeding metal interconnect in the second direction at an arrangement position of the feeding plug in a direction away from the interconnect plug.

With this configuration, the interconnect plug which connects the first circuit metal interconnect to the second circuit metal interconnect provided above the first circuit metal interconnect is disposed near the feeding plug which connects the first feeding metal interconnect to the second feeding metal interconnect provided above the first feeding metal interconnect. The center of the feeding plug in the second direction is shifted from the center of the first feeding metal interconnect in the second direction at the arrangement position of the feeding plug in a direction away from the interconnect plug. That is, the feeding plug is displaced in a direction away from the interconnect plug. Thus, a satisfactory interval can be ensured between the feeding plug and the interconnect plug which are close to each other, so that a problem where the plugs are electrically short-circuited can be avoided without increasing the area.

With the present disclosure, the stability of circuit operation can be maintained with the area being reduced and a satisfactory interval being ensured between the feeding plug and the interconnect plug.

### BRIEF DESCRIPTION OF THE DRAWINGS

FIG. 1 is a view illustrating an example layout pattern of a semiconductor integrated circuit device according to a first embodiment.

FIG. 2 is a view illustrating the layout pattern of FIG. 1, where metal interconnects and second plugs are omitted.

FIG. 3 is a view illustrating the layout pattern of FIG. 1, where active regions and gate interconnects are omitted.

FIG. 4 is a layout plan view illustrating rows of cells above which power supply strap interconnects are disposed.

FIG. 5 is a view illustrating the cross-sectional structure along the line A-A′ of FIG. 1.

FIG. 6 is a view illustrating another example layout pattern of the semiconductor integrated circuit device according to the first embodiment.

FIG. 7 is a view illustrating still another example layout pattern of the semiconductor integrated circuit device according to the first embodiment.

FIG. 8 is a view illustrating an example layout pattern of a semiconductor integrated circuit device according to a second embodiment.

FIG. 9 is a view illustrating another example layout pattern of the semiconductor integrated circuit device according to the second embodiment.

FIG. 10 is view illustrating an example layout of a latch circuit cell.

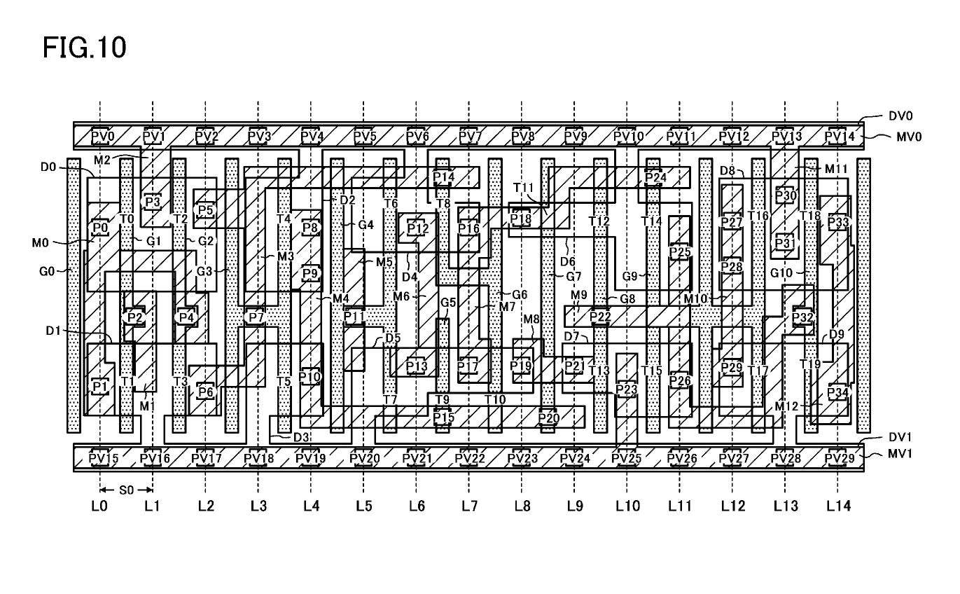

FIG. 11 is view illustrating an example in which a conventional technique is applied to the layout of FIG. 10.

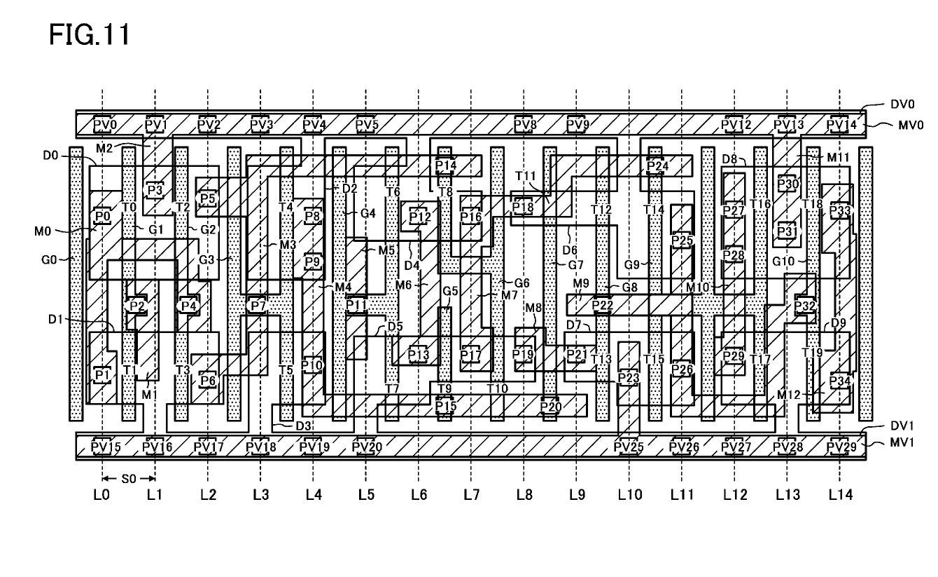

### DETAILED DESCRIPTION

Embodiments of the present disclosure will be described in detail below with reference to the drawings.

### First Embodiment

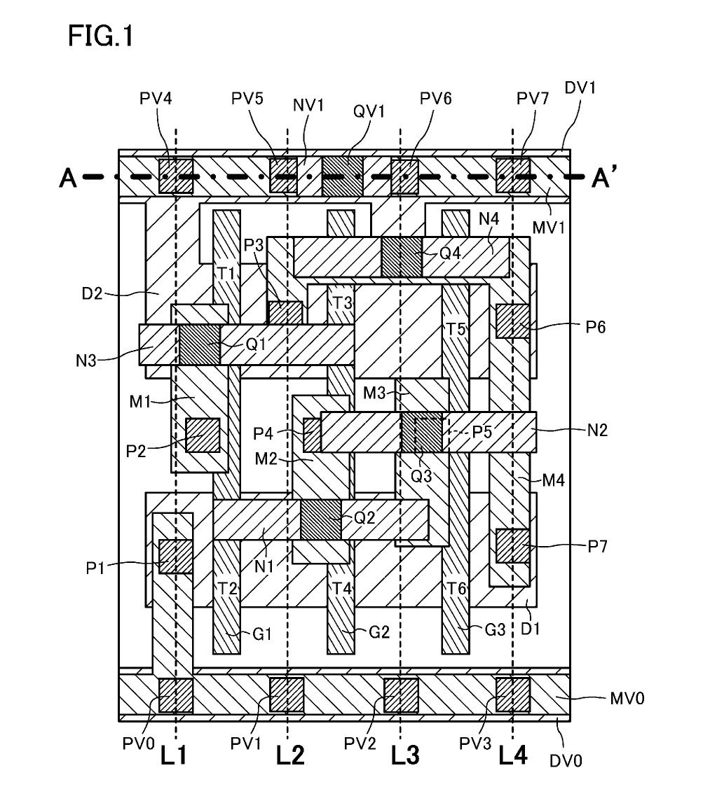

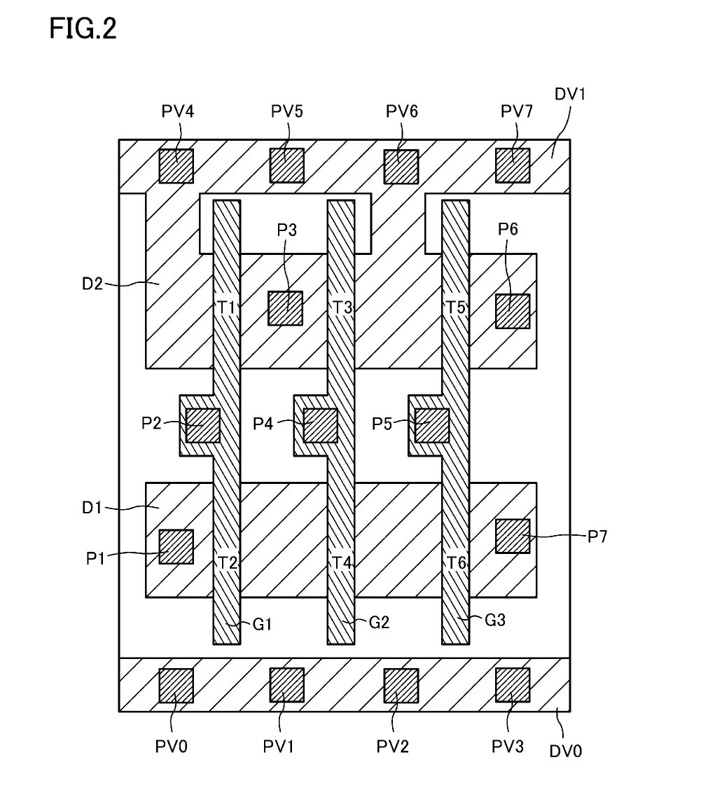

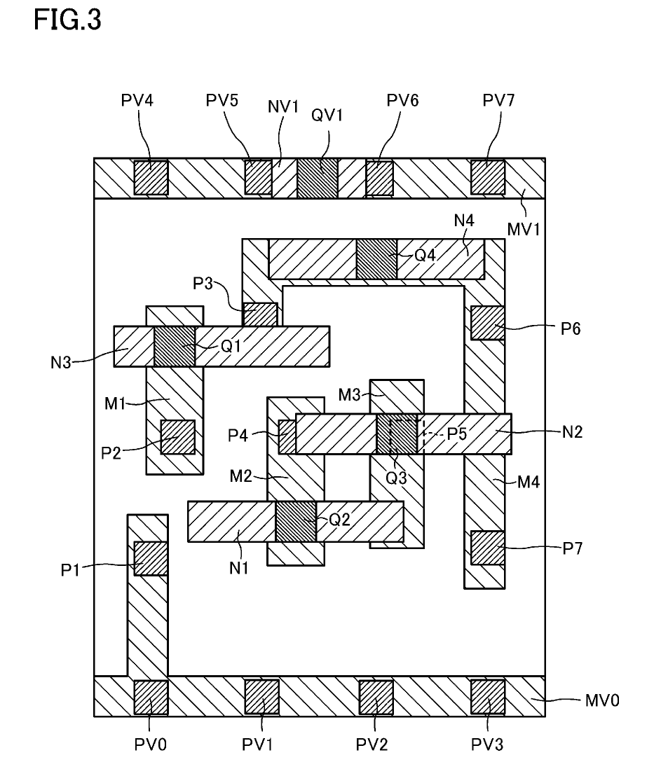

FIG. 1 is a plan view illustrating an example layout pattern of a semiconductor integrated circuit device according to a first embodiment. In FIG. 1, a configuration of one standard cell (standard logic cell) is illustrated. FIG. 1 shows active regions and gate interconnects included in transistors such as, for example, MISFETs, first-layer metal interconnects provided in a first interconnect layer above the active regions and the gate interconnects, first plugs which electrically connect the gate interconnects or the active regions to the first-layer metal interconnects, second-layer metal interconnects provided in a second interconnect layer above the first-layer metal interconnects, and second plugs which electrically connect the first-layer metal interconnects to the second-layer metal interconnects. Note that FIGS. 2 and 3 show easy-to-read views of the configuration of FIG. 1. In FIG. 2, the first-layer and second-layer metal interconnects and the second plugs of FIG. 1 are omitted, and only the gate interconnects, the active regions, and the first plugs are illustrated. In FIG. 3, the active regions and the gate interconnects of FIG. 1 are omitted, and only the first-layer and second-layer metal interconnects and the first and second plugs are illustrated.

In FIG. 1, feeding active regions DV0-DV1 are configured to supply source potentials of the transistors, and extend in the transverse direction in the figure (first direction) at upper and lower ends of the cell. Feeding first-layer metal interconnects MV0-MV1 are provided above the feeding active regions DV0-DV1, respectively. The feeding active region DV0 and the feeding first-layer metal interconnect MV0 are electrically connected to each other via a plurality of feeding first plugs PV0-PV3 formed therebetween. Likewise, the feeding active region DV1 and the feeding first-layer metal interconnect MV1 are electrically connected to each other via a plurality of feeding first plugs PV4-PV7 formed therebetween.

Between the feeding active regions DV0, DV1, active regions D1-D2 serving as the sources or the drains of the transistors, and gate interconnects G1-G3 serving as the gates of the transistors are provided, thereby forming transistors T1-T6. The active regions are defined by forming a shallow-trench-type isolation region referred to as, for example, shallow trench isolation (STI) or shallow groove isolation (SGI) on a principal surface of a semiconductor substrate. The gate interconnects are made of, for example, a polysilicon film, and are patterned on the principal surface of the semiconductor substrate via a gate insulating film made of a thin silicon oxide film, or the like.

Between the feeding active regions DV0, DV1, circuit first-layer metal interconnects M1-M4 are provided in the first interconnect layer above the active regions D1-D2 and the gate interconnects G1-G3. A plurality of interconnect first plugs P1-P7 are provided to electrically connect the active regions D1-D2 and the gate interconnects G1-G3 to the circuit first-layer metal interconnects M1-M4. Circuit second-layer metal interconnects N1-N4 are provided in the second interconnect layer above the circuit first-layer metal interconnects M1-M4. A plurality of interconnect second plugs Q1-Q4 are provided to electrically connect the circuit first-layer metal interconnects M1-M4 to the circuit second-layer metal interconnects N1-N4. Active regions and gate interconnects electrically connected to each other via circuit metal interconnects offer functions of circuits such as, for example, NAND circuits and flip-flop circuits.

Here, FIG. 1 illustrates a feeding second-layer metal interconnect NV1 and a feeding second plug QV1 which are included in a stacked via structure configured to supply power from a power supply strap interconnect formed in, for example, a fourth metal interconnect layer to the feeding first-layer metal interconnect MV1. Note that in FIG. 1, for simple description purposes, interconnects and plugs above a second metal interconnect layer are omitted.

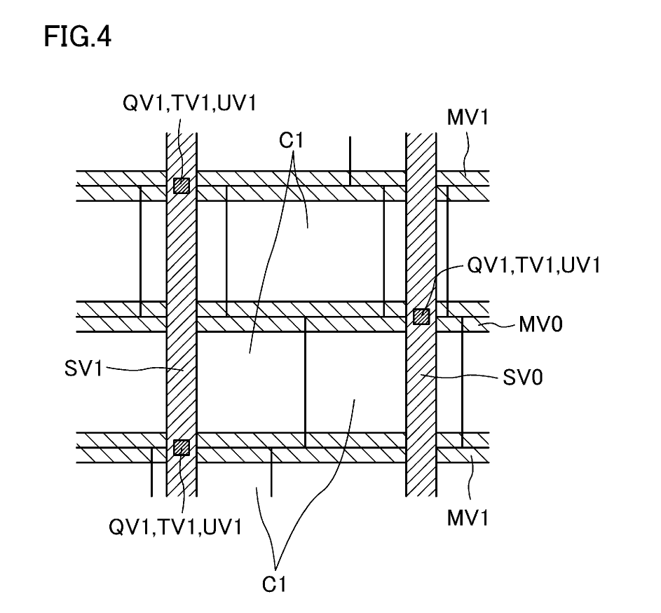

FIG. 4 is a layout plan view illustrating an example of a circuit region including the layout pattern of FIG. 1. As illustrated in FIG. 4, standard cells C1 each having the layout pattern illustrated in FIG. 1 are aligned in the transverse direction in the figure, thereby forming a row of standard cells sandwiched between the feeding first-layer metal interconnects MV0, MV1. Rows of the standard cells are aligned in the longitudinal direction in the figure. In the fourth metal interconnect layer above the rows of the standard cells, power supply strap interconnects SV0, SV1 are arranged to extend in the longitudinal direction in the figure which is perpendicular to a direction in which the feeding first-layer metal interconnects MV0, MV1 extend. The feeding first-layer metal interconnects MV0, MV1 are respectively connected to the power supply strap interconnects SV0, SV1 via feeding plugs QV1, TV1, UV1 arranged as a stack.

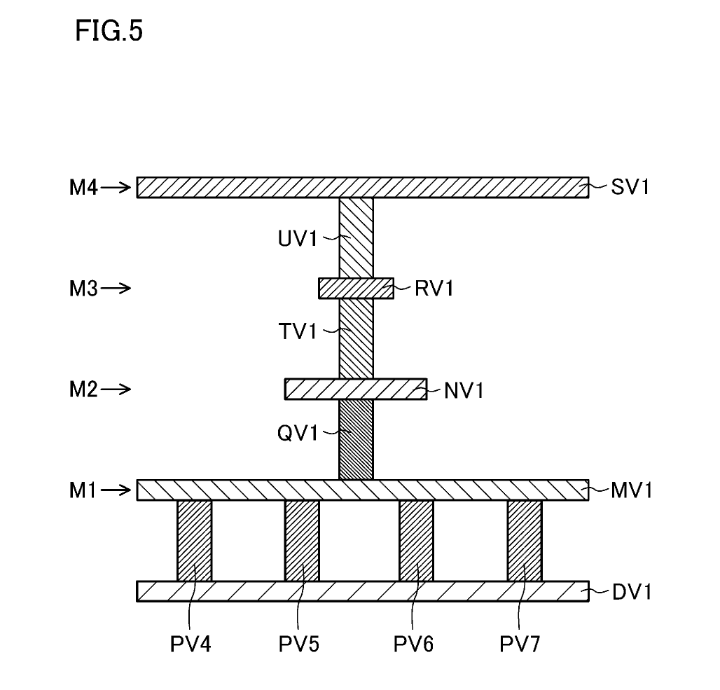

FIG. 5 is a view illustrating the cross-sectional structure along the line A-A′ of FIG. 1. In FIG. 5, the power supply strap interconnect SV1 is formed in the fourth metal interconnect layer (M4). The feeding first-layer metal interconnect MV1 is electrically connected to the power supply strap interconnect SV1 via the feeding second plug QV1, the feeding second-layer metal interconnect NV1, the feeding third plug TV1, a feeding third layer metal interconnect RV1, and the feeding fourth plug UV1 which are arranged as a stack.

In order to reduce an IR drop of the feeding first-layer metal interconnect MV1, the feeding second plug QV1 is generally disposed at any position on the feeding first-layer metal interconnect MV1 extending in the transverse direction in the figure. Meanwhile, in order to obtain a circuit function of the cell whose height is reduced to reduce the area, as many resources as possible have to be ensured for the circuit second-layer metal interconnects which can be disposed in the cell. Thus, the feeding second-layer metal interconnect NV1 is disposed as close as possible to the circuit second-layer metal interconnect N4 so that, for example, the interval between the feeding second-layer metal interconnect NV1 and the circuit second-layer metal interconnect N4 is a minimum value acceptable in the process rule. However, in this case, the feeding second plug QV1 disposed on the feeding second-layer metal interconnect NV1 is too close to the interconnect second plug Q4 disposed on the circuit second-layer metal interconnect N4, thereby forming a short circuit between the plugs, so that desired circuit operation cannot be obtained. However, when the feeding second plug QV1 is omitted as in the case of Japanese Patent Publication No. 2010-067799 described above, power supply from the power supply strap interconnect in an upper metal interconnect layer is no longer possible.

Thus, in the present embodiment, the interconnect second plug Q4 is disposed on a grid line L3, and the feeding second plug QV1 is disposed between a grid line L2 and the grid line L3. That is, the interconnect second plug Q4 and the feeding second plug QV1 are displaced relative to each other in the transverse direction in the figure. With this layout, a satisfactory interval can be ensured between the interconnect second plug Q4 and the feeding second plug QV1, so that it is possible to avoid a problem where a short circuit is formed between the plugs. Moreover, it is not necessary to extend the semiconductor integrated circuit device in the longitudinal direction in the figure, so that the layout area is not increased.

That is, in the configuration of the present embodiment, the interconnect MV1 serving as a first feeding metal interconnect formed in the first interconnect layer and extending in the transverse direction in the figure (first direction) and the second feeding metal interconnect NV1 formed in the second interconnect layer and extending in the first direction to overlap the interconnect MV1 are connected to each other via the plug QV1 serving as a feeding plug formed therebetween. Moreover, in the standard logic cell, the interconnect M4 serving as a first circuit metal interconnect formed in the first interconnect layer and the interconnect N4 serving as a second circuit metal interconnect formed in the second interconnect layer and extending in the first direction to overlap the interconnect M4 are connected to each other via the plug Q4 serving as an interconnect plug formed therebetween. Moreover, the interconnect N4 is disposed in the standard logic cell to be closer to the interconnect NV1 than any other circuit metal interconnects formed in the second interconnect layer are, and have a portion overlapping the interconnect NV when viewed in the longitudinal direction in the figure (second direction). The feeding plug QV1 and the interconnect plug Q4 are arranged in different positions in the transverse direction in the figure. In other words, when viewed in the longitudinal direction in the figure, the feeding plug QV1 has no portion overlapping the interconnect plug Q4.

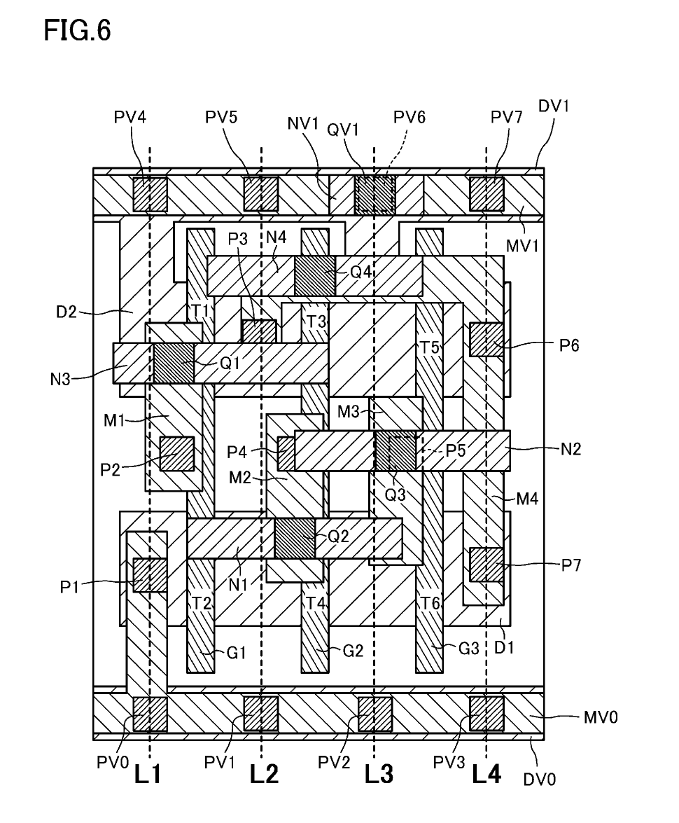

FIG. 6 is a plan view illustrating another example layout pattern of the semiconductor integrated circuit device according to the present embodiment. The configuration of the FIG. 6 is almost similar to that of FIG. 1. However, in FIG. 1, the interconnect second plug Q4 is disposed on the grid line L3, and the feeding second plug QV1 is disposed between the grid lines L2, L3, whereas in FIG. 6, an interconnect second plug Q4 is disposed between grid lines L2, L3, and a feeding second plug QV1 is disposed on the grid line L3. Also in the configuration of FIG. 6, the interconnect second plug Q4 is displaced relative to the feeding second plug QV1 in the transverse direction in the figure, and thus advantages similar to those of the configuration of FIG. 1 can be obtained.

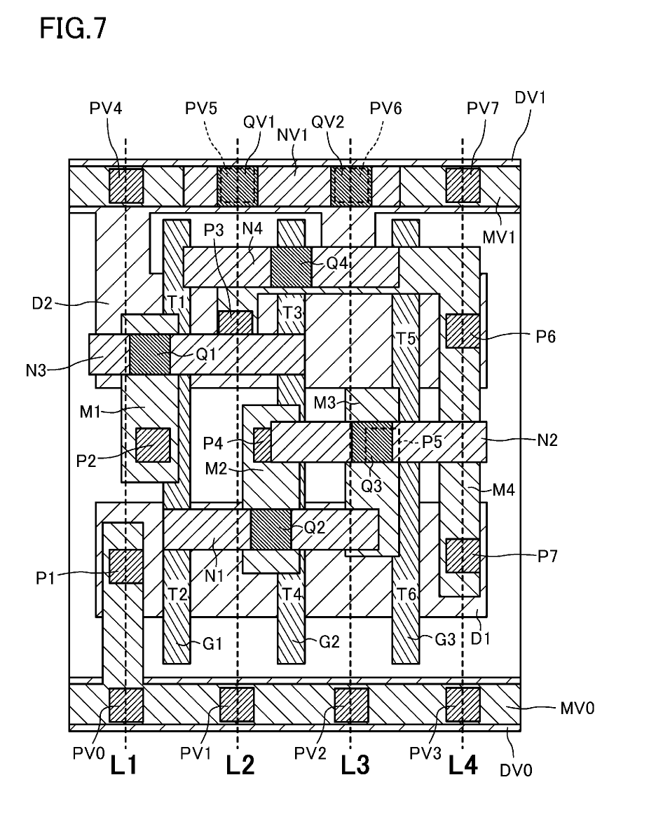

FIG. 7 is a plan view illustrating still another example layout pattern of the semiconductor integrated circuit device according to the present embodiment. The configuration of FIG. 7 is almost similar to that of FIG. 1, but is different from that of FIG. 1 in that two feeding second plugs QV1, QV2 are provided to connect an interconnect MV1 to an interconnect NV1. An interconnect second plug Q4 is disposed between grid lines L2, L3, the feeding second plug QV1 and the feeding second plug QV2 are disposed on the grid line L2 and the grid line L3, respectively. That is, both the feeding second plugs QV1, QV2 are arranged in positions different from that of interconnect second plug Q4 in the transverse direction in the figure. Also in the configuration of FIG. 7, the interconnect second plug Q4 is displaced relative to the feeding second plugs QV1, QV2 in the transverse direction in the figure. Thus, advantages similar to those of the configuration of FIG. 1 can be obtained. Note that three or more feeding plugs may be provided.

Note that in the example configuration described above, for ease of design, positions in which the feeding second plug and the interconnect second plug are arranged are determined based on grid lines, but this is not intended to limit the present disclosure, and the plugs may be arranged in any positions as long as a satisfactory interval can be ensured in a relative positional relationship. For example, both the feeding second plug and the interconnect second plug may be arranged in positions other than on the grid lines.

### Second Embodiment

In the first embodiment, the interval between the feeding second plug and the interconnect second plug disposed close to the feeding second plug is ensured by displacing at least one of the plugs in the transverse direction in the figure (first direction). In contrast, in the second embodiment, the interval between the feeding second plug and the interconnect second plug disposed close to the feeding second plug is ensured by displacing at least one of the plugs in the longitudinal direction in the figure (second direction).

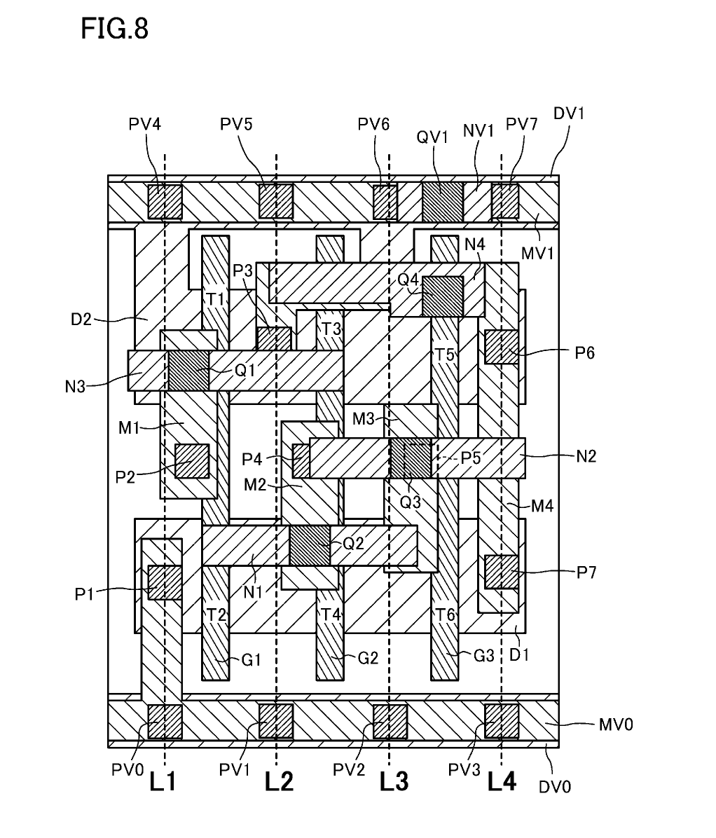

FIG. 8 is a plan view illustrating an example layout pattern of a semiconductor integrated circuit device according to the second embodiment. FIG. 8 is a view similar to FIG. 1, and shows a configuration of one standard cell (standard logic cell). FIG. 8 shows active regions and gate interconnects included in transistors such as, for example, MISFETs, first-layer metal interconnects provided in a first interconnect layer above the active regions and the gate interconnects, first plugs which electrically connect the gate interconnects or the active regions to the first-layer metal interconnects, second-layer metal interconnects provided in a second interconnect layer above the first-layer metal interconnects, and second plugs which electrically connect the first-layer metal interconnects to the second-layer metal interconnects. The same reference numerals as those shown in FIG. 1 are used to represent equivalent elements, and the detailed explanation thereof will be omitted.

In the configuration of FIG. 8, an interconnect second plug Q4 is displaced downward in the longitudinal direction in the figure to ensure the interval with respect to a feeding second plug QV1. Here, in order to ensure that the interconnect second plug Q4 overlaps a circuit second-layer metal interconnect N4, the circuit second-layer metal interconnect N4 has an L shape. That is, the circuit second-layer metal interconnect N4 has a larger width at a position on which the interconnect second plug Q4 is disposed than at other positions.

That is, in the configuration of FIG. 8, an interconnect MV1 serving as a first feeding metal interconnect formed in the first interconnect layer and extending in the transverse direction in the figure (first direction) and a second feeding metal interconnect NV1 formed in the second interconnect layer and extending in the first direction to overlap the interconnect MV1 are connected to each other via the plug QV1 serving as a feeding plug formed therebetween. Moreover, in the standard logic cell, an interconnect M4 serving as a first circuit metal interconnect formed in the first interconnect layer and the interconnect N4 serving as a second circuit metal interconnect formed in the second interconnect layer and extending in the first direction to overlap the interconnect M4 are connected to each other via the plug Q4 serving as an interconnect plug formed therebetween. Moreover, the interconnect N4 is disposed in the standard logic cell to be closer to the interconnect NV1 than any other circuit metal interconnect formed in the second interconnect layer are, and have a portion overlapping the interconnect NV1 when viewed in the longitudinal direction in the figure (second direction). The center of the interconnect plug Q4 in the longitudinal direction in the figure is shifted from the center of the interconnect N4 in the longitudinal direction in the figure at the arrangement position of the interconnect plug Q4 in a direction away from the feeding plug QV1.

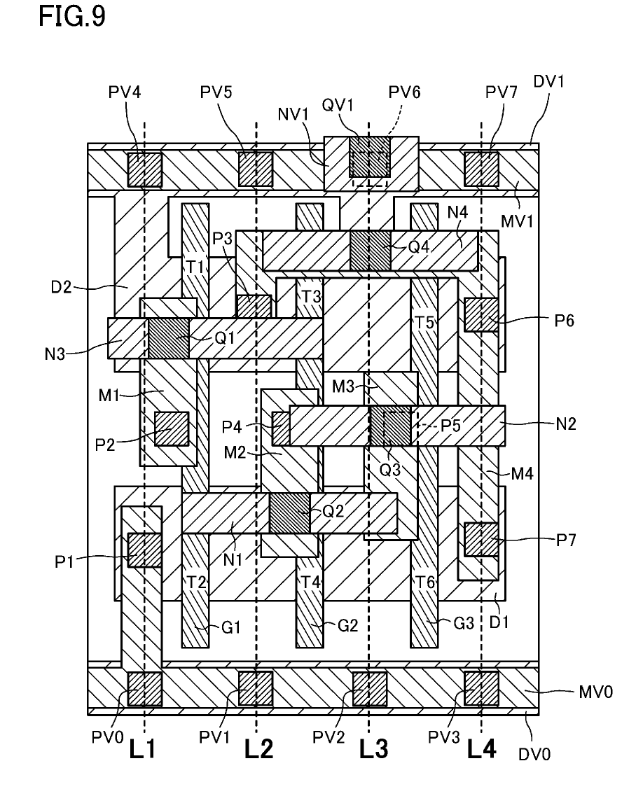

FIG. 9 is a plan view illustrating another example layout pattern of the semiconductor integrated circuit device according to the second embodiment. In the configuration of FIG. 9, a feeding second plug QV1 is displaced upward in the longitudinal direction in the figure to ensure the interval with respect to an interconnect second plug Q4. Here, in order to ensure that the feeding second plug QV1 overlaps a feeding second-layer metal interconnect NV1 and a feeding first-layer metal interconnect MV1, the width of the second feeding metal interconnect NV1 is increased, and the feeding first-layer metal interconnect MV1 has a protruding portion. That is, the feeding first-layer metal interconnect MV1 has a larger width at a position in which the feeding second plug QV1 is disposed than at other positions.

That is, in the configuration of the FIG. 9, the interconnect MV1 serving as a first feeding metal interconnect formed in the first interconnect layer and extending in the transverse direction in the figure (first direction) and the second feeding metal interconnect NV1 formed in the second interconnect layer and extending in the first direction to overlap the interconnect MV1 are connected to each other via the plug QV1 serving as a feeding plug formed therebetween. Moreover, in the standard logic cell, an interconnect M4 serving as a first circuit metal interconnect formed in the first interconnect layer and an interconnect N4 serving as a second circuit metal interconnect formed in the second interconnect layer and extending in the first direction to overlap the interconnect M4 are connected to each other via the plug Q4 serving as an interconnect plug formed therebetween. Moreover, the interconnect N4 is disposed in the standard logic cell to be closer to the interconnect NV1 than any other circuit metal interconnects formed in the second interconnect layer are, and have a portion overlapping the interconnect NV1 when viewed in the longitudinal direction in the figure (second direction). The center of the feeding plug QV1 in the longitudinal direction in the figure is shifted from the center of the interconnect MV1 in the longitudinal direction in the figure at the arrangement position of the feeding plug QV1 in a direction away from the interconnect plug Q4.

Also in the present embodiment, a satisfactory interval can be ensured between the interconnect second plug Q4 and the feeding second plug QV1, so that it is possible to avoid the problem where the plugs are electrically short-circuited. Moreover, the semiconductor integrated circuit device does not have to be extended in the longitudinal direction in the figure, so that the layout area is not increased.

Note that in the present embodiment, the feeding second plug QV1 and the interconnect second plug Q4 are aligned in positions in the transverse direction in the figure, but this is not intended to limit the present disclosure. For example, as in the first embodiment, the feeding second plug QV1 and the interconnect second plug Q4 may be displaced relative to each other in the transverse direction in the figure. That is, the present embodiment may be combined with the first embodiment. Alternatively, the feeding second plug QV1 and the interconnect second plug Q4 may be arranged to partially overlap each other when viewed in the longitudinal direction in the figure.

Moreover, the configuration of FIG. 8 may be combined with the configuration of FIG. 9.

Note that in the above-described configurations, in an actual semiconductor integrated circuit device, for example, the distance from the center of the feeding second plug to the center of the closest interconnect second plug is preferably longer than a length corresponding to 2.2 times the diameter of the feeding second plug.

In the present disclosure, for semiconductor integrated circuit devices, it is possible to maintain stability of circuit operation with the reduced area and a satisfactory interval between the feeding plug and the interconnect plug being ensured. Thus, for example, the present disclosure is useful to improve functional stability and to reduce cost of LSIs.

What is claimed is:

1. A semiconductor integrated circuit device including a standard logic cell, the semiconductor integrated circuit device comprising:
a first feeding metal interconnect formed in a first interconnect layer and extending in a first direction;
a second feeding metal interconnect formed in a second interconnect layer above the first interconnect layer and extending in the first direction to overlap the first feeding metal interconnect;
a first circuit metal interconnect formed in the first interconnect layer in the standard logic cell;
a second circuit metal interconnect formed in the second interconnect layer in the standard logic cell and extending in the first direction to overlap the first circuit metal interconnect;
a feeding plug configured to connect the first feeding metal interconnect to the second feeding metal interconnect; and
an interconnect plug configured to connect the first circuit metal interconnect to the second circuit metal interconnect, wherein
the second circuit metal interconnect is disposed in the standard logic cell to be closer to the second feeding metal interconnect than any other circuit metal interconnects formed in the second interconnect layer are, and have a portion overlapping the second feeding metal interconnect when viewed in a second direction perpendicular to the first direction, and
the feeding plug and the interconnect plug are arranged in different positions in the first direction.

2. The semiconductor integrated circuit device of claim 1, wherein
the feeding plug includes a plurality of feeding plugs, and
all of the plurality of feeding plugs are arranged in positions different from a position of the interconnect plug in the first direction.

3. A semiconductor integrated circuit device including a standard logic cell, the semiconductor integrated circuit device comprising:
a first feeding metal interconnect formed in a first interconnect layer and extending in a first direction;
a second feeding metal interconnect formed in a second interconnect layer above the first interconnect layer and extending in the first direction to overlap the first feeding metal interconnect;
a first circuit metal interconnect formed in the first interconnect layer in the standard logic cell;
a second circuit metal interconnect formed in the second interconnect layer in the standard logic cell and extending in the first direction to overlap the first circuit metal interconnect;
a feeding plug configured to connect the first feeding metal interconnect to the second feeding metal interconnect; and
an interconnect plug configured to connect the first circuit metal interconnect to the second circuit metal interconnect, wherein
the second circuit metal interconnect is disposed in the standard logic cell to be closer to the second feeding metal interconnect than any other circuit metal interconnects formed in the second interconnect layer are, and have a portion overlapping the second feeding metal interconnect when viewed in a second direction perpendicular to the first direction, and
a center of the interconnect plug in the second direction is shifted from a center of the second circuit metal interconnect in the second direction at an arrangement position of the interconnect plug in a direction away from the feeding plug.

4. A semiconductor integrated circuit device including a standard logic cell, the semiconductor integrated circuit device comprising:
a first feeding metal interconnect formed in a first interconnect layer and extending in a first direction;
a second feeding metal interconnect formed in a second interconnect layer above the first interconnect layer and extending in the first direction to overlap the first feeding metal interconnect;
a first circuit metal interconnect formed in the first interconnect layer in the standard logic cell;
a second circuit metal interconnect formed in the second interconnect layer in the standard logic cell and extending in the first direction to overlap the first circuit metal interconnect;
a feeding plug configured to connect the first feeding metal interconnect to the second feeding metal interconnect; and
an interconnect plug configured to connect the first circuit metal interconnect to the second circuit metal interconnect, wherein
the second circuit metal interconnect is disposed in the standard logic cell to be closer to the second feeding metal interconnect than any other circuit metal interconnects formed in the second interconnect layer are, and have a portion overlapping the second feeding metal interconnect when viewed in a second direction perpendicular to the first direction, and
a center of the feeding plug in the second direction is shifted from a center of the first feeding metal interconnect in the second direction at an arrangement position of the feeding plug in a direction away from the interconnect plug.

5. The semiconductor integrated circuit device of claim 3, wherein
the feeding plug and the interconnect plug are arranged to at least partially overlap each other when viewed in the second direction.

6. The semiconductor integrated circuit device of claim 1, wherein
the second feeding metal interconnect is connected to a power supply strap interconnect extending in the second direction in an interconnect layer above the second interconnect layer.

7. The semiconductor integrated circuit device of claim 1, wherein
a distance from a center of the feeding plug to a center of the interconnect plug is longer than a length corresponding to 2.2 times a diameter of the feeding plug.

8. The semiconductor integrated circuit device of claim 4, wherein
the feeding plug and the interconnect plug are arranged to at least partially overlap each other when viewed in the second direction.

9. The semiconductor integrated circuit device of claim 3, wherein
the second feeding metal interconnect is connected to a power supply strap interconnect extending in the second direction in an interconnect layer above the second interconnect layer.

10. The semiconductor integrated circuit device of claim 4, wherein
the second feeding metal interconnect is connected to a power supply strap interconnect extending in the second direction in an interconnect layer above the second interconnect layer.

11. The semiconductor integrated circuit device of claim 3, wherein
a distance from a center of the feeding plug to a center of the interconnect plug is longer than a length corresponding to 2.2 times a diameter of the feeding plug.

12. The semiconductor integrated circuit device of claim 4, wherein
a distance from a center of the feeding plug to a center of the interconnect plug is longer than a length corresponding to 2.2 times a diameter of the feeding plug.
